(19) United States
(12) Patent Application Publication
(10) Pub. No.: US 2006/0060947 A1
(43) Pub. Date: Mar. 23, 2006

(54) Method and apparatus for removing molding residues from lead-frames

(75) Inventor: Paolo Crema, Vimercate (MI) (IT)

Correspondence Address: FLEIT, KAIN, GIBBONS, GUTMAN, BONGINI;& BIANCO P.L., ONE BOCA COMMERCE CENTER, 551 NORTHWEST 77TH STREET, SUITE 111, BOCA RATON, FL, 33487, US

(73) Assignee: STMICROELECTRONICS S.r.l., AGRATE BRIANZA (IT)

(21) Appl. No.: 11/221,590

(22) Filed: Sep. 8, 2005

(30) Foreign Application Priority Data
Sep. 9, 2004 (EP) 04 104 349.8

(51) Int. Cl. H01L 23/495

(52) U.S. Cl. 257/666

(57) ABSTRACT

A method is provided for removing molding residues from surfaces of a lead-frame for electronic devices, with a portion of the lead-frame being exposed from at least one insulating body formed by the molding. According to the method, a flow of accelerated pellets of a frozen substance is generated, and at least one exposed surface of the lead-frame is hit with the generated flow. Also provided are a method of packaging electronic devices, and an apparatus for generating a flow of frozen pellets for removing molding residues from surfaces of a lead-frame.

### CROSS-REFERENCE TO RELATED APPLICATIONS

This application is based upon and claims priority from prior European Patent Application No. 04 104 349.8, filed Sep. 9, 2004, the entire disclosure of which is herein incorporated by reference.

### FIELD OF THE INVENTION

The present invention relates to package manufacturing processes for electronic devices, and more specifically to a process for removing manufacturing molding residues from lead-frames for electronic device packages.

### BACKGROUND OF THE INVENTION

An electronic device generally includes a circuit that is integrated on a chip of semiconductor material, which for its utilization must be housed in a package. The package includes an insulating body molded over the chip for protecting it, and, typically, multiple leads projecting from the insulating body to connect the chip to external circuits. The leads are in turn connected to the chip by tiny wires, e.g., of gold. The package further includes a paddle onto which the chip is mounted for holding the chip during subsequent manufacturing stages. The packaged electronic devices in most applications are mounted onto a Printed Circuit Board (PCB) and the leads are soldered to conductive strips of the PCB to make electrical connections. In packages for power applications, the paddle has a surface that is exposed with respect to the insulating body (such as the “exposed-pad” packages). In this case, the paddle acts as a heat dissipator, which is soldered in contact with the PCB.

These packages for electronic devices are fabricated from a lead-frame, which is typically produced by dieing or etching a thin metal plate. The lead-frame has a support frame structure, from which the leads project, connected to a plurality of die paddles by interconnection bars (that support the die paddles during the package manufacturing process).

Recently, the problem of environmental pollution by lead (Pb) has become very well known and many regulations have been enacted to prevent the use of lead in the manufacture of new electronic devices. Accordingly, many solutions have been adopted to avoid the use of standard SnPb solders and to improve solderability and wire bondability of Pb-free lead-frames. Particularly, in many applications lead-frames (typically of copper, Cu) are treated before the chip assembly by plating the whole surface thereof with additional metal layers (pre-plated lead-frames) for obtaining the required properties.

For example, copper lead-frames treated with exterior coatings of less oxidizable metals compatible with existing technology, such as nickel (Ni), palladium (Pd) and gold (Au), have been developed (Ni/Pd/Au pre-plated lead-frames). Palladium plating film has good gold wire bondability and solderability, so it is suitable for IC lead-frames. The Pd-plated lead-frame needs a nickel plating underlayer to maintain high joint strength of soldering parts; for example, the nickel layer is on the order of one micrometer and approximately 0.1 μm of palladium is plated thereon. In addition, the Pd-plated lead-frame is expected to be more likely stable against heat when further plated with an ultra-thin layer (tens of angstroms) of gold on the Pd-film surface.

However, it has to be considered that the insulating body, in which the electronic device is embedded, is produced by a molding process of a plastic material, which can cause flashes and bleeds over the metal surface of the leads and the exposed paddle (when exposed from the insulating body). Such molding residues on the lead-frame can impair the planarity of the surface of the electronic device that has to be soldered, for example, to the PCB; furthermore, the solderability of the leads and the die paddle of the electronic device can be greatly reduced. In addition, due to these problems, the heat dissipation capability of the die paddle and the electrical properties of the leads are impaired.

Solutions known in the art for removing the molding residues from the lead-frames propose different types of processes, such as mechanical or chemical/electro-chemical processes, or processes exploiting lasers. Particularly, known mechanical processes use a blasting in which solid particles, such as particles of sand, brass, or other powders, are accelerated to hit the surface of the lead-frames. By the mechanical effect of the collision of these solid particles against the lead-frame, the relatively thin layer of molding residues is removed from the metal surface of the lead-frames; similarly, for the same purpose and by a similar mechanical effect, water jets can also be exploited.

Mechanical and laser processes can be very aggressive on the metal surface of the lead-frames and can damage the superficial metal layers, especially the ultra-thin layer of the pre-plated lead-frames (such as the Ni/Pd/Au pre-plated lead-frames), so as to impair the solderability properties. In addition, wet processes, e.g., exploiting water jets, or chemical/electro-chemical processes, exploiting some kind of chemical agent, cannot be used in automated assembly lines operating in clean rooms. Typically, wet processes leave traces of the exploited agent on the packages and, furthermore, produce waste to possibly causing environmental damages (such as a toxic chemical agent exploited in a chemical process).

### SUMMARY OF THE INVENTION

In view of the problems described above, it is an object of the present invention to provide a process for removing molding residues from lead-frames without damaging the metal surface thereof.

Another object of the present invention is to provide a process that is compatible with automated assembly line operation and environmentally friendly.

One embodiment of the present invention provides a method of removing molding residues from surfaces of a lead-frame for electronic devices, with a portion of the lead-frame being exposed from at least one insulating body formed by the molding. According to the method, a flow of accelerated pellets of a frozen substance is generated, and at least one exposed surface of the lead-frame is hit with the flow that is generated.

Another embodiment of the present invention provides a method of packaging electronic devices. According to the method, a lead-frame is provided for electronic devices, with the lead-frame including a support plate and leads for each of the electronic devices. At least one chip is mounted onto a first surface of the support plate, and a plastic material is molded so as to embed the chip, a portion of the leads, and a portion of the support plate. At least a portion of a second surface of the support plate, which is opposite the first surface, is not embedded in the plastic material. Molding residues are removed from the second surface of the support plate and from an exposed portion of the leads by hitting the second surface of the support plate and the exposed portion of the leads with a flow of accelerated pellets of a frozen substance.

A further embodiment of the present invention provides an apparatus for generating a flow of frozen pellets for removing molding residues from surfaces of a lead-frame for electronic devices, with a portion of the lead-frame being exposed from at least one insulating body formed by the molding. The apparatus includes a generator of frozen material blocks, a sizer unit for obtaining frozen pellets from the frozen material blocks, and a propeller for accelerating the frozen pellets so as to generate a flow of frozen pellets.

Other objects, features, and advantages of the present invention will become apparent from the following detailed description. It should be understood, however, that the detailed description and specific examples, while indicating preferred embodiments of the present invention, are given by way of illustration only and various modifications may naturally be performed without deviating from the present invention.

### BRIEF DESCRIPTION OF THE DRAWINGS

FIG. 1 shows partial bottom plan and sectional side elevated views of a lead-frame onto which a chip is mounted after a molding process of a plastic material;

FIG. 2A illustrates a portion of an automated assembly line for a package manufacturing process for electronic devices in which a deflashing process according to an embodiment of the present invention is applied;

FIG. 2B shows in greater detail a portion of the automated assembly line in which a flow of dry ice pellets is generated to be exploited in the deflashing process; and

FIG. 3 is a partial sectional side elevated view of the lead-frame having flashes on its exposed surface during the deflashing process according to an embodiment of the present invention.

### DETAILED DESCRIPTION OF PREFERRED EMBODIMENTS

Preferred embodiments of the present invention will be described in detail hereinbelow with reference to the attached drawings.

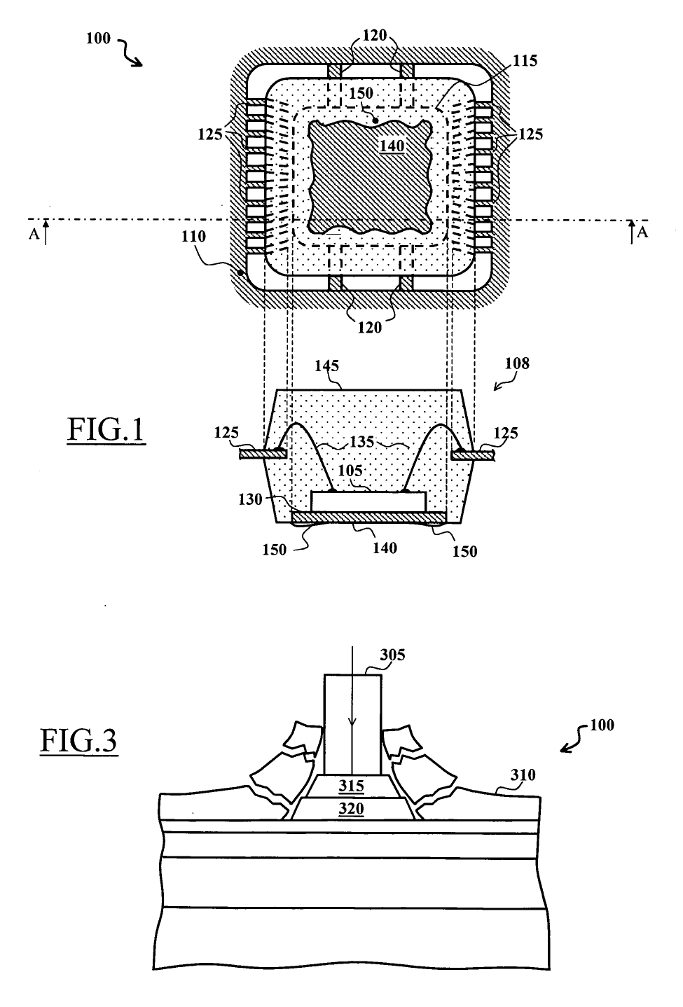

With reference to the drawings, FIG. 1 illustrates partial bottom plan and sectional elevated side views of a lead-frame 100, onto which electronic circuits integrated in chips 105 of semiconductor material are mounted. Particularly, the lead-frame 100 is exploited for obtaining leaded packages for electronic devices 108, e.g., to be mounted onto a PCB.

The lead-frame 100 is produced from a conductive plate, typically, a metal plate, such as a copper plate, having a thickness, for example, on the order of a few millimeters. The lead-frame 100 includes a support frame structure 110 and die mounting paddles 115 (only one is shown in the drawing) formed in the metal plate. The paddle 115, having roughly a square shape, primarily serves to mechanically hold one or more chips 105 on its upper surface 130 during a package manufacturing process. The paddle 115 in turn is connected to the support frame 110 by a plurality of interconnection bars 120. The lead-frame 100 further includes a plurality of leads 125 for each paddle 115; the leads 125 project from respective portions of the support frame 110 facing, for example, two opposite sides of the paddle 115.

The lead-frame 100 is plated with additional metal layers in order to improve the solderability and the wire bondability. For example, the lead-frame 100 is first plated with nickel, so as to obtain a layer with a thickness of, e.g., hundreds of nanometers. A layer of a precious metal, such as palladium, of about tens of nanometers covers the nickel layer. Finally, the lead-frame 100 is plated with a further precious metal, such as gold; typically, the gold layer is very thin, e.g., in the range of 30-150 angstroms.

The packaged electronic device 108 includes the chip 105 mounted onto the upper surface 130 of the paddle 115, with the chip 105 being electrically connected to proximal ends of the corresponding leads 125 by tiny metal wires 135 (typically, made of gold). The leads 125 are in turn connectable to external circuits.

Typically, a plane of the paddles 115 is spaced apart from a plane of the leads 125. Such a downsetting of the paddle 115 with respect to the leads 125 allows a better looping of the wires 135 to be achieved. A deep downsetting of the paddle 115 allows the paddle to maintain its lower surface 140 (opposite the upper surface 130 onto which the chip 105 is mounted) exposed from an insulating body 145 of the packaged electronic device 108.

The insulating body 145 (made of a plastic material, such as an epoxy resin) protects the chip 105 and the wires 135. The insulating body 145 also embeds (in addition to the chip 105 and the wires 135) an internal portion of the leads 125 (to which the wires 135 are connected) and a portion of the interconnection bars 120 extending from the paddle 115. Conversely, an active portion of the leads 125 extending from the support frame 110 of the lead-frame 100 is maintained outside the insulating body 145.

Typically, the packaged electronic device 108 is mounted onto a PCB, which has an insulating substrate on which conductive strips are patterned. For this purpose, the exposed surface 140 of the paddle 115 is soldered onto the PCB and the leads 125 are mechanically and electrically connected to the desired conductive strips of the PCB. The paddle 115 in contact with the PCB improves the heat dissipation during the electronic device 108 operation by forming a heat flow path between the chip 105 and the PCB (the paddle 115 acts as a heat dissipator). Additionally, the paddle 115 can be connected to ground, thus reducing loop inductance for high-frequency applications; in such applications the paddle 115 is called an “exposed pad”.

The lead-frame 100 is produced by dieing (or by etching) the metal plate, so as to define the support frame 110, the paddles 115, the interconnection bars 120 and the leads 125. Before assembling chips 105 on its surface, the lead-frame 100 is pre-plated with additional metal layers, as described above, so as to obtain, for example, three additional relatively thin layers of nickel, palladium and gold.

During a package manufacturing process in an automated assembly line, one or more chips 105 are mounted onto each paddle 115 of the lead-frame 100 and fixed thereto by a binding material (such as an adhesive compound). The chip 105 is then connected to the corresponding leads 125 through the gold wires 135.

The complex of the chip 105 and the wires 135 is embedded into the insulating body 145, for example made of an epoxy resin, by a molding process, with the lower surface 140 of the paddle 115 as well as the active portion of the leads 125 being kept exposed. In the molding process high temperature and pressure liquefies the epoxy resin, which is then forced through a mold chase into a cavity over the chips 105 mounted onto the lead-frame 100. The epoxy resin, once hardened, forms the body of the final package.

The packaged electronic devices thus obtained are then separated from each other and from the support frame 110 of the lead-frame 100 by cropping the portions of the interconnection bars 120 projecting from the insulating body 145 and the end portions of the leads 125 connected to the support frame 110.

During the molding process, residues 150 of epoxy resin, such as flashes or bleeds, inevitably form on the exposed surface 140 of the paddle 115 and on the active portion of the leads 125. The molding residues 150 cause a reduction in the heat dissipation capability of the paddle 115, as well as a reduction of the solderability, because of an impaired planarity and a decreased area to be placed directly in contact with, e.g., the PCB. In addition, the molding residues 150 impair the electrical properties of the leads 125 and the paddle 115 (when exploited as an exposed pad).

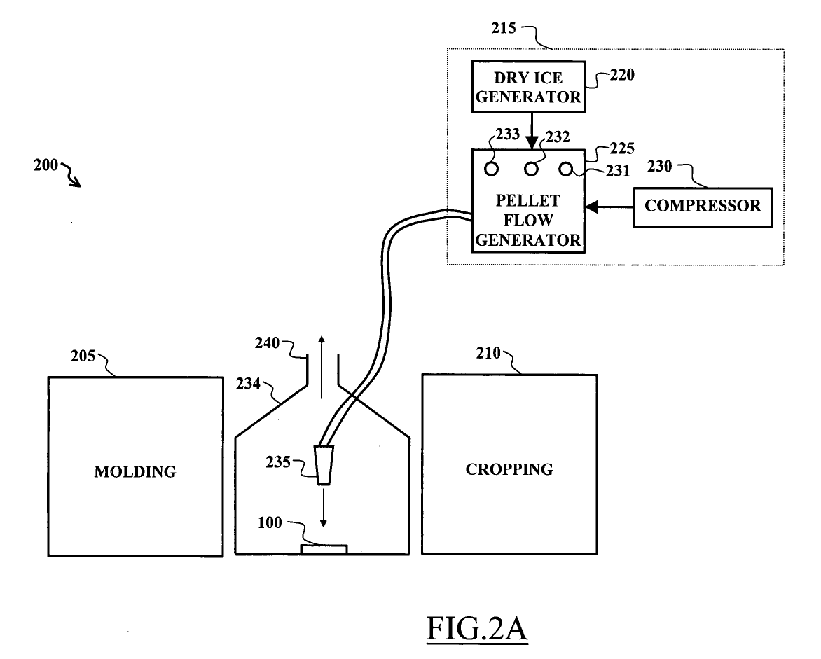

FIG. 2A shows a portion of the automated assembly line 200 for a package manufacturing process in which a deflashing process according to an embodiment of the present invention is applied.

After the molding process and before cropping the lead-frame 100 for separating the packaged electronic devices from each other, which are performed in respective portions 205 and 210 of the automated line 200, a deflashing process is performed for removing the molding residues (i.e., residues of the molding process) from the lead-frame 100. Particularly, the deflashing process according to this embodiment of the present invention includes a blasting in which suitable pellets are projected against the lead-frame surface to be cleaned.

In detail, in this exemplary embodiment, the automated line 200 includes a cryogenic apparatus 215 that is adapted to produce pellets of a frozen substance, preferably (but not limited to) dry ice (e.g., solid carbon dioxide, CO₂) pellets, and project such pellets against the lead-frame. Dry ice is frozen carbon dioxide obtained by solidification at a temperature of about −78.5° C.; solid carbon dioxide is called “dry ice” since, in normal atmospheric conditions, it changes directly from a solid phase to a gaseous phase (i.e., it sublimates) without passing through a liquid phase.

The cryogenic apparatus 215 includes a dry ice generator 220 in which dry ice is produced, for example in the form of roughly cylindrical dry ice elements having a diameter on the order of a few millimeters (for example, of about 2 mm).

The dry ice cylindrical elements are provided by the dry ice generator 220 to a pellet flow generator 225 (such as the Cryos Cryojet BG 01 model) that also receives dried compressed air from a compressor 230. The pellet flow generator 225 is adapted to regulate the injection pressure of the compressed air (for example, between 2 and 15 bar), and for this purpose the pellet flow generator 225 is provided with a suitable regulation knob 231.

As shown in FIG. 2B, the pellet flow generator 225 exploits the propelling force of the compressed air 245 for projecting the received cylindrical dry ice elements 250 against an internal grid 255, which acts as a sieve, with, e.g., square passages having a size in a range from approximately 0.5 mm to 2 mm, and preferably in a range from approximately 0.6 mm to 1.4 mm. In this way, the pellet flow generator 225 generates a flow 260 of dry ice pellets having a size depending on the size of the grid passages (e.g., approximately of 0.8 mm), accelerated by the compressed air 245. The size of the dry ice pellets is limited so as not to have an excessive mass, and thus an excessive momentum when accelerated, so as not to cause bending of the leads.

Referring back to FIG. 2A, the pellet flow generator 225 is preferably provided with two further regulation knobs 232 and 233 for regulating a carrying pressure of the compressed air (for example, between approximately 3 and 7 bar) and a pellet carrying capacity (for example, between approximately 20-150 kg/h) of the pellet flow, respectively.

The lead-frame 100 is exposed, preferably in a clean room 234, to the dry ice pellet flow provided from the pellet flow generator 225, for example by a nozzle 235 (e.g., a nozzle of a gun). The dry ice pellet flow is directed against the lead-frame surface to be cleaned with regulated pressure and pellet carrying capacity.

The automated line 200 is provided with an exhaust system 240 for eliminating waste produced by the deflashing process, with the waste being molding residues removed from the lead-frame surface and a harmless carbon dioxide gas, produced by sublimation of the dry ice.

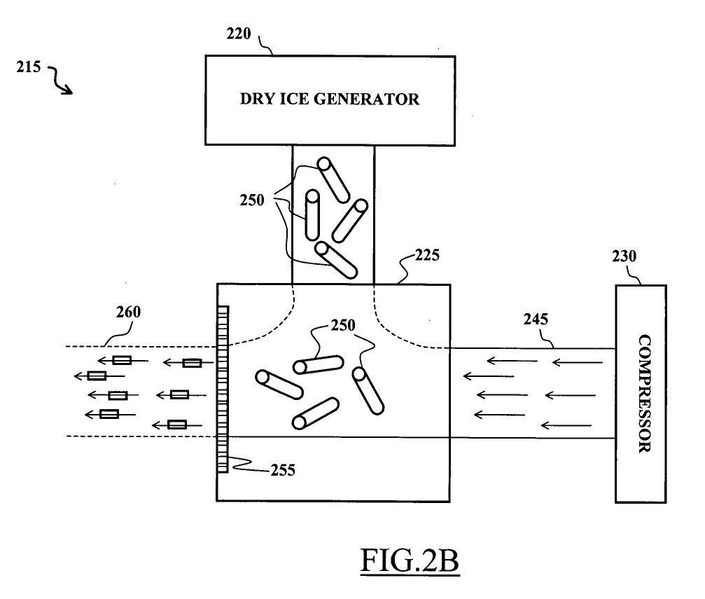

FIG. 3 illustrates the action of the dry ice pellet flow against the surface of the lead-frame 100 to be cleaned.

First, a dry ice pellet 305, propelled out of the nozzle at a relatively high speed, impacts the surface of the molding residue layer 310. The flow of dry ice pellets is preferably (but not limitedly) oriented approximately orthogonal to the surface of the lead-frame to be cleaned.

Typically, the molding residue layer 310 has a thickness of about some tens of micrometers (such as 10 to 40 μm) and the transfer of the momentum of the pellet 305 to the molding residue layer 310 permits the pellets to penetrate the surface thereof, without however damaging the insulating body, which has a much greater thickness.

The metal area exposed from the insulating body of the package does not endure abrasion, due to the dry ice having a hardness of approximately 1 on the Mohs scale (i.e., close to the talc hardness) and substantially immediately passing, upon impacting the surface of the insulating body, to a powdered form 315.

The lead-frame is preferably heated above the room temperature, for example, to a temperature of about 80° C., and a thermal shock between the surface of the molding residue layer 310 and the lead-frame 100 follows the impact of the pellet 305, the pellet being at a low temperature of about −78° C. Cracking of the molding residues subsequent to the thermal shock then favors elimination thereof.

In addition, the dry ice pellet 305 “explodes” on impact, passing from the powdered form 315 to a gaseous form 320 thanks to the sudden substantial increase in temperature. In fact, as the pellet 305 warms when it comes in contact with a surface (e.g., the surface of the molding residue layer 310) that is at a temperature much higher than that of the pellet, it sublimates, directly converting to a harmless gas, which expands rapidly underneath the surface of the molding residue layer 310. The pressure of the carbon dioxide gas and the compressed air carrying the pellet flow forces off the cracked molding residue layer 310 from the lead-frame 100 without leaving traces of carbon dioxide on the surface thereof.

The surface of the lead-frame to be cleaned is exposed to the pellet flow for a relatively short period, for example of a few seconds (such as 2-3 seconds).

The deflashing process according to this embodiment of the present invention does not damage the thin superficial metal layer plating the lead-frame and, accordingly, does not impair the solderability and the heat dissipation capability thereof. This deflashing process is mainly based on a thermal effect acting on the plastic material layer that has a relatively thin thickness. This thermal effect arises from the high temperature difference between the lead-frame surface and the “frozen” pellets, and it cracks the thin plastic material layer. Furthermore, the sublimated pellet applies a pressure inside the cracks in the plastic residue layer, which permits it to be taken off without abrasion of the metal surface.

The mechanical effect of the deflashing process is limited to a relatively “soft” impact of the dry ice pellets onto the lead-frame surface and to the pressure due to the expansion of the carbon dioxide in the gaseous phase.

In addition, the process according to this embodiment of the present invention is not a wet process, and can be applied in an automated assembly line operating in a clean room.

Furthermore, a gas, such as carbon dioxide, is absolutely harmless and not a pollutant, and can be easily eliminated from the automated assembly line without causing environmental damages.

Alternatively, the “frozen” pellets may be made of a different material or composition of materials, which, similarly to carbon dioxide, sublimates or passes sufficiently rapidly from a solid (“frozen”) phase to a gaseous phase when undergoing an appropriate change in temperature and/or pressure, e.g., a relatively high temperature difference in pressure conditions close to the atmospheric one. A valid alternative to the carbon dioxide can be, for example, hyponitrous oxide (or nitrogen protoxide, N₂O).

Although the present invention has been disclosed and described by way of an embodiment, it is apparent to those skilled in the art that several modifications to the described embodiment, as well as other embodiments of the present invention are possible without departing from the scope thereof as defined in the appended claims.

For example, the lead-frame can be made of a different material and can be plated with different materials that do not exhibit an excessive adhesion to the molding compound (such as copper). The lead-frame can have a different structure and the leads can be arranged facing only one side of the die or facing all the sides of the die. The relatively small pellets can be produced in a different way, such as by a device different than a grid.

Additionally, many modifications may be made to adapt a particular situation to the teachings of the present invention without departing from the central inventive concept described herein. Furthermore, an embodiment of the present invention may not include all of the features described above. Therefore, it is intended that the present invention not be limited to the particular embodiments disclosed, but that the invention include all embodiments falling within the scope of the appended claims.

What is claimed is:

1. A method of removing molding residues from surfaces of a lead-frame for at least one electronic device, a portion of the lead-frame being exposed from at least one insulating body formed by the molding, the method comprising the steps of:
generating a flow of accelerated pellets of a frozen substance; and
hitting at least one exposed surface of the lead-frame with the flow that is generated.

2. The method of removing molding residues according to claim 1, wherein the step of generating the flow of accelerated pellets comprises sizing a diameter of the pellets in a range from approximately 0.5 mm to approximately 2 mm.

3. The method of removing molding residues according to claim 1, wherein the step of generating the flow of accelerated pellets comprises sizing a diameter of the pellets in a range from approximately 0.6 mm to approximately 1.4 mm.

4. The method of removing molding residues according to claim 1, wherein the step of generating the flow of accelerated pellets includes propelling the pellets by dried compressed air.

5. The method of removing molding residues according to claim 4, wherein propelling the pellets includes regulating a pressure of the dried compressed air in a range from approximately 2 bar to approximately 7 bar.

6. The method according to claim 1, wherein the step of generating the flow of accelerated pellets includes regulating a carrying capability of the flow in a range from approximately 20 kg/h to approximately 150 kg/h.

7. The method according to claim 1, wherein the frozen substance is solid carbon dioxide.

8. The method according to claim 1, wherein the hitting step includes causing the pellets to sublimate.

9. A method of packaging electronic devices, the method comprising the steps of:
providing a lead-frame for at least one electronic device, the lead-frame comprising a support plate and a plurality of leads for the electronic device;
mounting at least one chip onto a first surface of the support plate;
molding a plastic material so as to embed the at least one chip, a portion of the leads, and a portion of the support plate, such that at least a portion of a second surface of the support plate, which is opposite the first surface, is not embedded in the plastic material; and
removing molding residues from the second surface of the support plate and from an exposed portion of the leads by hitting the second surface of the support plate and the exposed portion of the leads with a flow of accelerated pellets of a frozen substance.

10. The method according to claim 9, wherein the removing step comprises sizing a diameter of the pellets in a range from approximately 0.5 mm to approximately 2 mm.

11. The method according to claim 9, wherein the removing step comprises propelling the pellets by dried compressed air.

12. The method according to claim 9, wherein the removing step comprises regulating a carrying capability of the flow in a range from approximately 20 kg/h to approximately 150 kg/h.

13. The method according to claim 9, wherein the frozen substance is solid carbon dioxide.

14. The method according to claim 9, wherein the removing step comprises causing the pellets to sublimate.

15. An apparatus for generating a flow of frozen pellets for removing molding residues from surfaces of a lead-frame for at least one electronic device, a portion of the lead-frame being exposed from at least one insulating body formed by the molding, the apparatus comprising:
a generator of frozen material blocks;
a sizer unit for obtaining frozen pellets with a size in a prescribed range from the frozen material blocks; and
a propeller for accelerating the frozen pellets so as to generate a flow of frozen pellets.

16. The apparatus according to claim 15, wherein the sizer unit includes a sieve, and the propeller accelerates the frozen material blocks against the sieve.

17. The apparatus according to claim 15, wherein the sizer unit produces the frozen pellets with a diameter in a range from approximately 0.5 mm to approximately 2 mm.

18. The apparatus according to claim 15, wherein the propeller accelerates the frozen pellets using dried compressed air.

19. The apparatus according to claim 15, further comprising at least one regulator for regulating a carrying capability of the flow in a range from approximately 20 kg/h to approximately 150 kg/h.

20. The apparatus according to claim 15, wherein the frozen material blocks comprise solid carbon dioxide.
